(19) United States
(12) Patent Application Publication
(10) Pub. No.: US 2026/0032814 A1
(43) Pub. Date: Jan. 29, 2026

(54) SEMICONDUCTOR PACKAGE CARRIER BOARD STRUCTURE AND MANUFACTURING METHOD THEREOF

(71) Applicant: PHOENIX PIONEER TECHNOLOGY CO., LTD., Hsinchu County (TW)

(72) Inventors: Chao-Ching Tseng, Hsinchu County (TW); Shih-Ping Hsu, Hsinchu County (TW)

(21) Appl. No.: 19/283,457

(22) Filed: Jul. 29, 2025

(30) Foreign Application Priority Data
Jul. 29, 2024 (TW) 113128134

(51) Int. Cl. H05K 1/05; H05K 1/02; H05K 3/00; H05K 3/44

(52) U.S. Cl. CPC H05K 1/056; H05K 1/0296; H05K 3/0055; H05K 3/44; H05K 2201/0154; H05K 2201/032; H05K 2201/09563

(57) ABSTRACT

A semiconductor package carrier board structure is provided and includes a substrate body, a first dielectric material, and a second dielectric material. The substrate body has a first surface, a second surface opposite to the first surface, a plurality of first openings recessed from the first surface, a plurality of second openings recessed from the second surface, and a plurality of third openings. Two ends of the plurality of third openings are connected to the plurality of first openings and the plurality of second openings. The plurality of first openings are filled with the first dielectric material. The plurality of second openings and the plurality of third openings are filled with the second dielectric material. A method of manufacturing the semiconductor package carrier board structure is further provided.

### CROSS-REFERENCE TO RELATED APPLICATIONS

This Application claims the benefit of priority to Taiwan Patent Application No. 113128134, filed on Jul. 29, 2024 in Taiwan, the entire contents of which are incorporated herein by reference.

### BACKGROUND

### 1. Technical Field

The present disclosure relates to a semiconductor package carrier board structure, and more particularly, to a semiconductor package carrier board structure having unilateral secondary etching and a manufacturing method thereof.

### 2. Description of Related Art

With the evolution of semiconductor packaging technology, in smartphones, tablet computers, networks, laptop computers, and other products, semiconductor devices have been available in many different package types, such as ball grid array (BGA), quad-flat package (QFP), quad-flat no-leads (QFN) package, and so on.

FIG. 1 is a schematic cross-sectional view of a substrate structure 1 of a conventional package structure. As shown in FIG. 1, the conventional substrate structure 1 includes a substrate 10 having a first surface 10a and a second surface 10b opposite to the first surface 10a, a circuit layer 11 formed on the first surface 10a of the substrate 10, a conductive pillar 12 formed in the substrate 10, a surface treatment layer 13 formed on the circuit layer 11 and/or the conductive pillar 12, and a dielectric layer 14 formed on the second surface 10b of the substrate 10. In addition, the substrate 10 is a copper board.

Specifically, by double-sided half-etching the first surface 10a and the second surface 10b of the substrate 10, a double-sided etching structure is formed, and the circuit layer 11 and the conductive pillar 12 are formed. Subsequently, after performing the separation process, the surface treatment layer 13 is formed on the first surface 10a of the substrate 10, and a lamination process is utilized to laminate the dielectric layer 14 from the second surface 10b into the substrate 10, thereby completing the substrate structure 1.

However, the double-sided half-etching process of the substrate structure 1 of the conventional package structure is done by different vendors, resulting in the substrate structure 1 being left bare to the package vendors and requiring additional bracket connections, thereby resulting in limited product design capability. In addition, the packaging industry needs to perform processes such as etching, backside packaging, grinding, etc., thereby causing inconvenience to the packaging industry. Besides, since the conventional double-sided etching process requires etching through the substrate 10, it is easy to cause the problem of subsequent electrode detachment.

Therefore, how to overcome various problems of the above-mentioned prior art has become a difficult problem urgently to be overcome in the industry.

### SUMMARY

The present disclosure provides a semiconductor package carrier board structure, which comprises: a substrate body made of a conductive material and having a first surface and a second surface opposite to the first surface, the substrate body being formed with a plurality of first openings recessed from the first surface, a plurality of second openings recessed from the second surface, and a plurality of third openings, the plurality of first openings, the plurality of second openings, and the plurality of third openings defining a plurality of first conductive pillars and a plurality of second conductive pillars, wherein two ends of the plurality of third openings are connected to the plurality of first openings and the plurality of second openings, and a width of each of the plurality of third openings is less than a corresponding width of each of the plurality of second openings; a first dielectric material filling the plurality of first openings; and a second dielectric material filling the plurality of second openings and the plurality of third openings.

In the aforementioned semiconductor package carrier board structure, end surfaces of the plurality of first conductive pillars are flush with, recessed below, or protruding above a surface of the first dielectric material.

In the aforementioned semiconductor package carrier board structure, end surfaces of the plurality of second conductive pillars are flush with, recessed below, or protruding above a surface of the second dielectric material.

In the aforementioned semiconductor package carrier board structure, the second dielectric material in the plurality of third openings contacts the first dielectric material in the plurality of first openings.

In the aforementioned semiconductor package carrier board structure, the substrate body is made of copper, copper alloy, or nickel alloy.

In the aforementioned semiconductor package carrier board structure, the first dielectric material and the second dielectric material are made of at least one photosensitive or non-photosensitive organic dielectric material selected from a group consisting of Ajinomoto build-up film, polybenzoxazole, polyimide, prepreg with glass fibers, epoxy, epoxy molding compound, and bismaleimide triazine.

The present disclosure also provides a method of manufacturing a semiconductor package carrier board structure, and the method comprises: providing a substrate body having a first surface and a second surface opposite to the first surface, a material of the substrate body being a conductive material; forming a first patterned photoresist layer on the first surface of the substrate body, and forming a second patterned photoresist layer on the second surface of the substrate body; removing a portion of the material of the substrate body that is not covered by the first patterned photoresist layer and the second patterned photoresist layer by performing a first etching process to form a plurality of first openings from the first surface and a plurality of second openings from the second surface, the plurality of first openings defining a plurality of first conductive pillars, and the plurality of second openings defining a plurality of second conductive pillars, wherein the plurality of first openings and the plurality of second openings are not connected to each other; forming a first dielectric material on the first surface of the substrate body and the first patterned photoresist layer to fill the plurality of first openings and cover the first patterned photoresist layer; removing another portion of the material of the substrate body in the plurality of second openings to etch through a bottom of each of the plurality of second openings to form a plurality of third openings by performing a second etching process, wherein two ends of the plurality of third openings are connected to the plurality of first openings and the plurality of second openings, a portion of the first dielectric material is exposed from the plurality of third openings, and a width of each of the plurality of third openings is less than a corresponding width of each of the plurality of second openings; forming a second dielectric material on the second surface of the substrate body and the second patterned photoresist layer to fill the plurality of second openings and the plurality of third openings and cover the second patterned photoresist layer; and removing another portion of the first dielectric material and a portion of the second dielectric material, and removing all of the first patterned photoresist layer and all of the second patterned photoresist layer to expose end surfaces of the plurality of first conductive pillars and end surfaces of the plurality of second conductive pillars.

In the aforementioned method, after removing the another portion of the first dielectric material and all of the first patterned photoresist layer, the end surfaces of the plurality of first conductive pillars are flush with, recessed below, or protruding above a surface of the first dielectric material.

In the aforementioned method, after removing the portion of the second dielectric material and all of the second patterned photoresist layer, the end surfaces of the plurality of second conductive pillars are flush with, recessed below, or protruding above a surface of the second dielectric material.

In the aforementioned method, the second dielectric material in the plurality of third openings contacts the first dielectric material in the plurality of first openings.

In summary, in the semiconductor package carrier board structure and the manufacturing method thereof according to the present disclosure, by utilizing a double-sided etching process that does not etch through a substrate body, a dielectric material is formed on one side of the substrate body, and subsequently the other side of the substrate body is subjected to another single etching process until the substrate body is etched through and filled with another dielectric material, such that the dielectric materials can increase the thickness of the substrate body and increase the contact area between the dielectric materials and the substrate body so as to enable the semiconductor package carrier board structure with good toughness and stability and to ensure the effectiveness of the structure, thereby forming a super-thin carrier board and a package structure and avoiding the problem of electrode detachment caused by etching through the substrate body in a conventional double-sided etching process at the same time.

Moreover, the double-sided dielectric material can effectively clamp the conductive pillars to get a good bonding, thereby reducing problems of electrical failure due to impacts or drops in the packaged or subsequent electronic products. In the present disclosure, in addition to synchronized double-sided etching to save processing time, the photoresist does not require additional removal process, but only needs to be removed in the planarization process. Therefore, the manufacturing method of the present disclosure is simple, effectively saves processing time, is low in cost, and imposes no design limitations.

### BRIEF DESCRIPTION OF THE DRAWINGS

FIG. 1 is a schematic cross-sectional view of a substrate structure of a conventional package structure.

FIG. 2A to FIG. 2F are schematic cross-sectional views illustrating a method of manufacturing a semiconductor package carrier board structure according to the present disclosure.

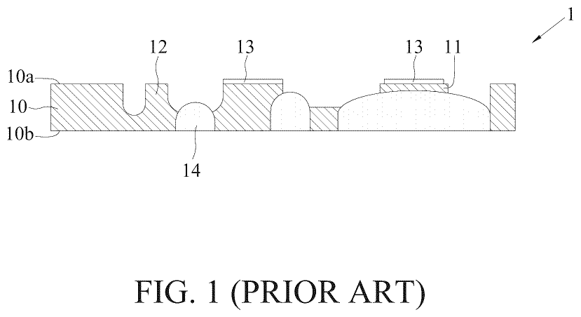

### DETAILED DESCRIPTION

The following describes the implementation of the present disclosure with examples. Those skilled in the art can easily understand other advantages and effects of the present disclosure from the contents disclosed in this specification.

It should be understood that the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “one,” “a,” “an,” “first,” “second,” “on,” “beneath,” and the like are for clear explanation rather than limiting the practicable scope of the present disclosure, and thus, alterations or adjustments of the relative relationships thereof without essentially altering the technical contents should still be considered in the practicable scope of the present disclosure.

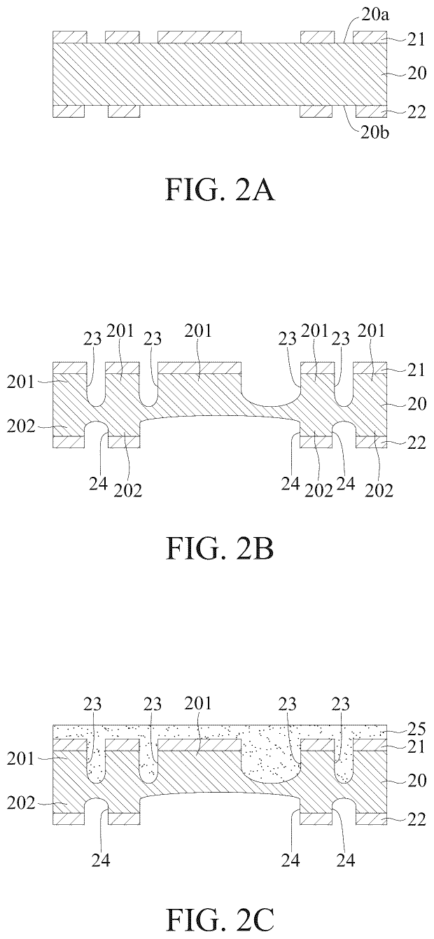

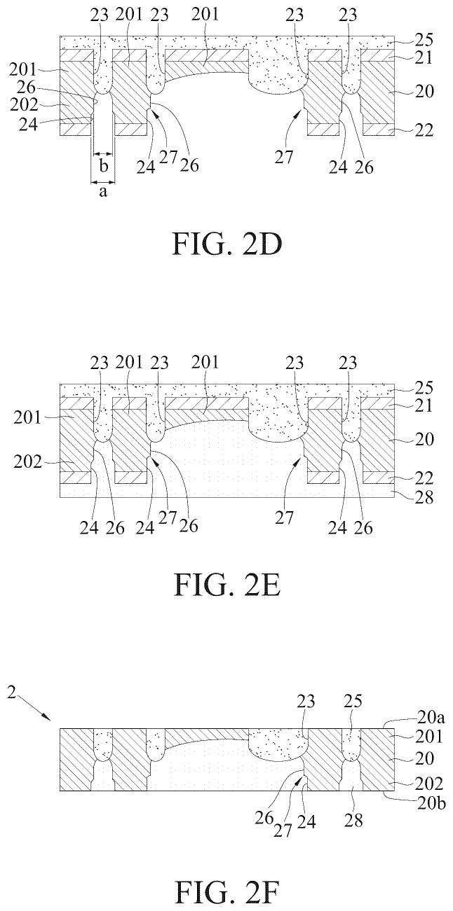

FIG. 2A to FIG. 2F are schematic cross-sectional views illustrating a method of manufacturing a semiconductor package carrier board structure 2 according to the present disclosure.

As shown in FIG. 2A, a substrate body 20, a first patterned photoresist layer 21, and a second patterned photoresist layer 22 are provided.

In an embodiment, the substrate body 20 has a first surface 20a and a second surface 20b opposite to the first surface 20a. The first patterned photoresist layer 21 is formed on the first surface 20a, and a portion of the first surface 20a is exposed. The second patterned photoresist layer 22 is formed on the second surface 20b, and a portion of the second surface 20b is exposed.

In an embodiment, the material of the substrate body 20 is a conductive material, which may be, for example, a copper foil of copper, a copper alloy, a nickel alloy, or a metal material for heat dissipation.

As shown in FIG. 2B, a portion of material of the substrate body 20 is removed by a first etching process on the first surface 20a and the second surface 20b of the substrate body 20 that are not covered by the first patterned photoresist layer 21 and the second patterned photoresist layer 22, respectively. A plurality of first openings 23 are formed from the first surface 20a, and a plurality of second openings 24 are formed from the second surface 20b.

In an embodiment, the first openings 23 and the second openings 24 are not connected to each other. The portions of the substrate body 20 between the plurality of first openings 23 may be defined as a plurality of first conductive pillars 201, and the portions of the substrate body 20 between the plurality of second openings 24 may be defined as a plurality of second conductive pillars 202. In addition, the peripheral sidewalls of the first conductive pillars 201 and the second conductive pillars 202 are concave in shape.

As shown in FIG. 2C, a first dielectric material 25 is formed on the first surface 20a of the substrate body 20 and the first patterned photoresist layer 21 by a lamination process, such that the first dielectric material 25 covers the first patterned photoresist layer 21 and fills the plurality of first openings 23.

In an embodiment, the first dielectric material 25 is made of at least one photosensitive or non-photosensitive organic dielectric material, selected from a group consisting of Ajinomoto build-up film (ABF), polybenzoxazole (PBO), polyimide (PI), prepreg (PP) with glass fibers, epoxy (epoxy resin), epoxy molding compound (EMC), and bismaleimide triazine (BT).

As shown in FIG. 2D, a portion of material of the substrate body 20 is removed by a second etching process in the plurality of second openings 24 of the second surface 20b of the substrate body 20 to etch through the bottom of each of the second openings 24 to form a plurality of third openings 26.

In an embodiment, two ends of the plurality of third openings 26 are connected to the plurality of first openings 23 and the plurality of second openings 24, and the first dielectric material 25 in the first openings 23 is exposed from the third openings 26. Further, there is an offset boundary 27 between the second openings 24 and the third openings 26, such that the width b of each of the third openings 26 is less than the width a of each of the second openings 24.

In an embodiment, the second etching process may etch a portion of the first conductive pillar 201 between any two of the first openings 23 to form a third opening 26.

As shown in FIG. 2E, a second dielectric material 28 is formed on the second surface 20b of the substrate body 20 and the second patterned photoresist layer 22 by a lamination process, such that the second dielectric material 28 covers the second patterned photoresist layer 22 and fills the plurality of second openings 24 and the plurality of third openings 26.

In an embodiment, the second dielectric material 28 in the third openings 26 contacts the first dielectric material 25 in the first openings 23.

In an embodiment, the second dielectric material 28 is made of at least one photosensitive or non-photosensitive organic dielectric material, selected from a group consisting of Ajinomoto build-up film (ABF), polybenzoxazole (PBO), polyimide (PI), prepreg (PP) with glass fibers, epoxy (epoxy resin), epoxy molding compound (EMC), and bismaleimide triazine (BT).

As shown in FIG. 2F, a planarization process is performed to remove all of the first patterned photoresist layer 21, all of the second patterned photoresist layer 22, a portion of the first dielectric material 25, and a portion of the second dielectric material 28 by, for example, a grinding method, to expose the end surfaces of the plurality of first conductive pillars 201 and the end surfaces of the plurality of second conductive pillars 202, so that a surface of the first dielectric material 25 is flush with the end surfaces of the first conductive pillars 201, and a surface of the second dielectric material 28 is flush with the end surfaces of the second conductive pillars 202, thereby obtaining the semiconductor package carrier board structure 2 of the present disclosure. In other embodiments, the end surfaces of the first conductive pillars 201 may be recessed below or protruding above a surface of the first dielectric material 25, and the end surfaces of the second conductive pillars 202 may be recessed below or protruding above a surface of the second dielectric material 28, but not limited thereto.

The present disclosure also provides a semiconductor package carrier board structure 2, comprising a substrate body 20, a first dielectric material 25, and a second dielectric material 28.

The substrate body 20 is made of a conductive material and has a first surface 20a and a second surface 20b opposite to the first surface 20a, and the substrate body 20 has a plurality of first openings 23 recessed from the first surface 20a, a plurality of second openings 24 recessed from the second surface 20b, and a plurality of third openings 26.

In an embodiment, two ends of the plurality of third openings 26 are connected to the plurality of first openings 23 and the plurality of second openings 24, and the plurality of third openings 26 are located between the plurality of first openings 23 and the plurality of second openings 24. Further, there is an offset boundary 27 between the second openings 24 and the third openings 26, such that the width b of each of the third openings 26 is less than the width a of each of the second openings 24.

Further, the portions of the substrate body 20 between the plurality of first openings 23 may be defined as a plurality of first conductive pillars 201, and the portions of the substrate body 20 between the plurality of second openings 24 and between the plurality of third openings 26 may be defined as a plurality of second conductive pillars 202. In addition, the peripheral sidewalls of the plurality of first conductive pillars 201 and the plurality of second conductive pillars 202 are concave in shape.

In an embodiment, the material of the substrate body 20 is a conductive material, which may be, for example, a copper foil of copper, a copper alloy, a nickel alloy, or a metal material for heat dissipation.

The first dielectric material 25 fills the plurality of first openings 23, and the end surfaces of the plurality of first conductive pillars 201 are flush with, recessed below, or protruding above a surface of the first dielectric material 25.

The second dielectric material 28 fills the plurality of second openings 24 and the plurality of third openings 26, and the end surfaces of the plurality of second conductive pillars 202 are flush with, recessed below, or protruding above a surface of the second dielectric material 28. Further, the second dielectric material 28 in the plurality of third openings 26 contacts the first dielectric material 25 in the plurality of first openings 23.

In an embodiment, the first dielectric material 25 and the second dielectric material 28 are made of at least one photosensitive or non-photosensitive organic dielectric material, selected from a group consisting of Ajinomoto build-up film (ABF), polybenzoxazole (PBO), polyimide (PI), prepreg (PP) with glass fibers, epoxy (epoxy resin), epoxy molding compound (EMC), and bismaleimide triazine (BT).

In summary, in the semiconductor package carrier board structure and the manufacturing method thereof according to the present disclosure, by utilizing a double-sided etching process that does not etch through a substrate body, a dielectric material is formed on one side of the substrate body, and subsequently the other side of the substrate body is subjected to another single etching process until the substrate body is etched through and filled with another dielectric material, such that the dielectric materials can fill the etched portion of the substrate body and increase the contact area between the dielectric materials and the substrate body so as to enable the semiconductor package carrier board structure with good toughness and stability and to ensure the effectiveness of the structure, thereby forming a super-thin carrier board and a package structure and avoiding the problem of electrode detachment caused by etching through the substrate body in a conventional double-sided etching process at the same time.

Furthermore, the double-sided dielectric material can effectively clamp the conductive pillars to get a good bonding, thereby reducing problems of electrical failure due to impacts or drops in the packaged or subsequent electronic products. In the present disclosure, in addition to synchronized double-sided etching to save processing time, the photoresist does not require additional removal process, but only needs to be removed in the planarization process. Therefore, the manufacturing method of the present disclosure is simple, effectively saves processing time, is low in cost, and imposes no design limitations.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A semiconductor package carrier board structure, comprising:
a substrate body made of a conductive material and having a first surface and a second surface opposite to the first surface, the substrate body being formed with a plurality of first openings recessed from the first surface, a plurality of second openings recessed from the second surface, and a plurality of third openings, the plurality of first openings, the plurality of second openings, and the plurality of third openings defining a plurality of first conductive pillars and a plurality of second conductive pillars, wherein two ends of the plurality of third openings are connected to the plurality of first openings and the plurality of second openings, and a width of each of the plurality of third openings is less than a corresponding width of each of the plurality of second openings;
a first dielectric material filling the plurality of first openings; and
a second dielectric material filling the plurality of second openings and the plurality of third openings.

2. The semiconductor package carrier board structure of claim 1, wherein end surfaces of the plurality of first conductive pillars are flush with, recessed below, or protruding above a surface of the first dielectric material.

3. The semiconductor package carrier board structure of claim 1, wherein end surfaces of the plurality of second conductive pillars are flush with, recessed below, or protruding above a surface of the second dielectric material.

4. The semiconductor package carrier board structure of claim 1, wherein the second dielectric material in the plurality of third openings contacts the first dielectric material in the plurality of first openings.

5. The semiconductor package carrier board structure of claim 1, wherein the substrate body is made of copper, copper alloy, or nickel alloy.

6. The semiconductor package carrier board structure of claim 1, wherein the first dielectric material and the second dielectric material are made of at least one photosensitive or non-photosensitive organic dielectric material selected from a group consisting of Ajinomoto build-up film, polybenzoxazole, polyimide, prepreg with glass fibers, epoxy, epoxy molding compound, and bismaleimide triazine.

7. A method of manufacturing a semiconductor package carrier board structure, comprising:
providing a substrate body having a first surface and a second surface opposite to the first surface, a material of the substrate body being a conductive material;
forming a first patterned photoresist layer on the first surface of the substrate body, and forming a second patterned photoresist layer on the second surface of the substrate body;
removing a portion of the material of the substrate body that is not covered by the first patterned photoresist layer and the second patterned photoresist layer by performing a first etching process to form a plurality of first openings from the first surface and a plurality of second openings from the second surface, the plurality of first openings defining a plurality of first conductive pillars, and the plurality of second openings defining a plurality of second conductive pillars, wherein the plurality of first openings and the plurality of second openings are not connected to each other;
forming a first dielectric material on the first surface of the substrate body and the first patterned photoresist layer to fill the plurality of first openings and cover the first patterned photoresist layer;
removing another portion of the material of the substrate body in the plurality of second openings to etch through a bottom of each of the plurality of second openings to form a plurality of third openings by performing a second etching process, wherein two ends of the plurality of third openings are connected to the plurality of first openings and the plurality of second openings, a portion of the first dielectric material is exposed from the plurality of third openings, and a width of each of the plurality of third openings is less than a corresponding width of each of the plurality of second openings;
forming a second dielectric material on the second surface of the substrate body and the second patterned photoresist layer to fill the plurality of second openings and the plurality of third openings and cover the second patterned photoresist layer; and
removing another portion of the first dielectric material and a portion of the second dielectric material, and removing all of the first patterned photoresist layer and all of the second patterned photoresist layer to expose end surfaces of the plurality of first conductive pillars and end surfaces of the plurality of second conductive pillars.

8. The method of claim 7, wherein after removing the another portion of the first dielectric material and all of the first patterned photoresist layer, the end surfaces of the plurality of first conductive pillars are flush with, recessed below, or protruding above a surface of the first dielectric material.

9. The method of claim 7, wherein after removing the portion of the second dielectric material and all of the second patterned photoresist layer, the end surfaces of the plurality of second conductive pillars are flush with, recessed below, or protruding above a surface of the second dielectric material.

10. The method of claim 7, wherein the second dielectric material in the plurality of third openings contacts the first dielectric material in the plurality of first openings.
